(19) United States
(12) Patent Application Publication
(10) Pub. No.: US 2008/0280442 A1
(43) Pub. Date: Nov. 13, 2008

(54) METHOD FOR FABRICATING SEMICONDUCTOR DEVICE

(75) Inventors: Sang-Hyon Kwak, Ichon-shi (KR); Kyoung-Sik Han, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/962,017

(22) Filed: Dec. 20, 2007

(30) Foreign Application Priority Data
May 9, 2007 (KR) 10-2007-0045064
Sep. 10, 2007 (KR) 10-2007-0091596

(51) Int. Cl. H01L 21/304

(52) U.S. Cl. 438/693; 257/E21.239

(57) ABSTRACT

A method for fabricating a semiconductor device is provided. A substrate includes two different regions, each of which has a different pattern density. A polish target layer is formed over the substrate to cover the patterns in the regions and a planarization guide layer is formed along a top surface of the polish target layer. The planarization guide layer has a polish selectivity ratio with respect to the polish target layer. Subsequently, the planarization guide layer formed in a first region is removed such that the planarization guide layer remains only in a second region having the patterns with low pattern density and the remaining planarization guide layer and the polish target layer are polished to remove a step between the first and second regions.

### CROSS-REFERENCES TO RELATED APPLICATIONS

The present invention claims priority of Korean patent application numbers 2007-0045064 and 2007-0091596, filed on May 9, 2007 and Sep. 10, 2007, respectively, which are incorporated by reference in their entirety.

### BACKGROUND OF THE INVENTION

The present invention relates to a method for fabricating a semiconductor device, and more particularly, to a method for planarizing a semiconductor device including a sparse region of low pattern density and a dense region of high pattern density.

NAND flash memory devices, nonvolatile memory devices, include a plurality of strings of which unit string is provided with a plurality cells connected in series for realizing high-integration degree. NAND flash memory device gradually expand their application areas to replace memory sticks, universal serial bus (USB) drivers and hard disks.

Like other semiconductor memory devices, a NAND flash memory is divided into two regions of which one is a cell region where memory cells are formed and the other is a peripheral region where driving circuits for driving the memory cells, for example, a decoder and a page buffer, are formed. Since a number of components are formed in each of the cell region and the peripheral region through the same or separate fabricating processes, there exists a step between the two regions.

There are several factors that cause the step between the cell region and the peripheral region in the NAND flash memory device. One of the most influencing factors is a pattern density difference between the cell region and the peripheral region. That is, a plurality of memory cells having narrow linewidths are densely arranged for storing data in the cell region, and thus a space between the memory cells is narrower than a space between logic devices formed in the peripheral region.

In fabricating a NAND flash memory device, an insulation layer is formed over a substrate to cover the substrate that includes the cell region with memory cells formed and the peripheral region with logic devices, e.g., transistors, formed. Subsequently, a planarization process is performed using a chemical mechanical polishing (CMP) method.

Hereinafter, a typical method of planarizing an insulation layer in a NAND flash memory device will be described with reference to FIGS. 1A to 1C. FIGS. 1A to 1C are cross-sectional views in which a symbol ‘CELL’ denotes a cell region, and a symbol ‘PERI’ denotes a peripheral region.

Referring to FIG. 1A, a gate electrode 107 for a cell (hereinafter, referred to as a first gate electrode) is formed in a cell region CELL, and a logic device, e.g., a gate electrode 108 for a transistor (hereinafter, referred to as a second gate electrode) is formed in a peripheral region PERI.

A spacer 109 is formed on both sidewalls of the first and the second gate electrodes 107 and 108. An etch stop layer 110, which will be used for a self aligned contact (SAC) during a subsequent etch process, is formed along top surfaces of the first and the second gate electrodes 107 and 108.

Referring to FIG. 1B, an inslation layer 111 is deposited such that it covers the etch stop layer 110.

Referring to FIG. 1C, a CMP process is performed to planarize the insulation layer 111. As a result, a polished insulation layer 111A is formed.

Although not described in detail, reference numeral 100 denotes a substrate, reference numeral 101 denotes a tunneling insulation layer (or a gate insulation layer), reference numeral 102 denotes a floating gate, reference numeral 103 denotes a dielectric layer, reference numeral 104 denotes a control gate (or a gate electrode), reference numeral 105 denotes a metal silicide layer, and reference numeral 106 denotes a hard mask layer.

The typical method of planarizing the NAND flash memory device has several limitations as described in detail below.

In FIG. 1A, a space between the first gate electrodes 107 formed in the cell region CELL is relatively narrower than a space between the second gate electrodes 108 formed in the peripheral region PERI. This is ascribed to a pattern density difference between the cell region CELL and the peripheral region PERI.

When the insulation layer 111 is deposited under such a state, as illustrated in FIG. 1B, the insulation layer 111 is deposited lower in the peripheral region PERI but deposited higher in the cell region CELL because there is a great difference in pattern space between the two regions CELL and PERI due to pattern density difference between the cell and peripheral regions CELL and PERI. Therefore, there occurs a step H₁ between the cell region CELL and the peripheral region PERI.

The CMP process may be performed to remove the step between the two regions CELL and PERI. However, as illustrated in FIG. 1C, the step between the two regions CELL and PERI is reduced in some degrees but it is difficult to completely remove the step. Typically, a new step H₂ still exists between the two regions CELL and PERI after the CMP process

Moreover, as shown in the micrographic views of FIG. 2, even after planarization of the insulation layer 111 by adopting the typical planarization method, it can be observed that steps between a central portion (a) and an edge portion (b) in the cell region CELL and the peripheral region (c) are not significantly removed.

### SUMMARY OF THE INVENTION

Embodiments of the present invention are directed to provide a method for fabricating a semiconductor device which can effectively remove steps existing between regions having different pattern densities.

In accordance with an aspect of the present invention, there is provided a method for fabricating a semiconductor device. The method includes providing a substrate including first and second regions of which each region has a plurality of patterns, the patterns in the first region having a pattern density different from the patterns in the second region, wherein the polish target layer covers the plurality of patterns. The method further includes forming a polish target layer over the substrate, forming a planarization guide layer along a top surface of the polish target layer, the planarization guide layer having a polish selectivity ratio with respect to the polish target layer, removing the planarization guide layer formed in the first region such that the planarization guide layer remains only in the second region having the patterns with low pattern density, and polishing the remaining planarization guide layer and the polish target layer to remove a step between the first and second regions.

In accordance with another aspect of the present invention, there is provided a method for fabricating a semiconductor device. The method includes providing a substrate including a cell region and a peripheral region of which each region has a plurality of gate electrodes. The gate electrodes in the cell region have a density different from the gate electrodes in the peripheral region, where the insulation layer covers the gate electrodes. The method further includes forming an insulation layer over the substrate, forming a planarization guide layer along a top surface of the insulation layer, the planarization guide layer having a polish selectivity ratio with respect to the insulation layer, removing the planarization guide layer formed in the cell region such that the planarization guide layer remains only in the peripheral region having the gate electrodes with low density, and polishing the remaining planarization guide layer and the insulation layer to remove a step between the cell region and the peripheral region.

### BRIEF DESCRIPTION OF THE DRAWINGS

FIGS. 1A to 1C are cross-sectional views of a typical method of planarizing an insulation layer.

FIG. 2 is a micrographic view of a typical semiconductor device.

FIGS. 3A to 3E are cross-sectional views of a method for fabricating a semiconductor device in accordance with an embodiment of the present invention.

FIG. 4 is a micrographic view of a semiconductor device in accordance with an embodiment of the present invention.

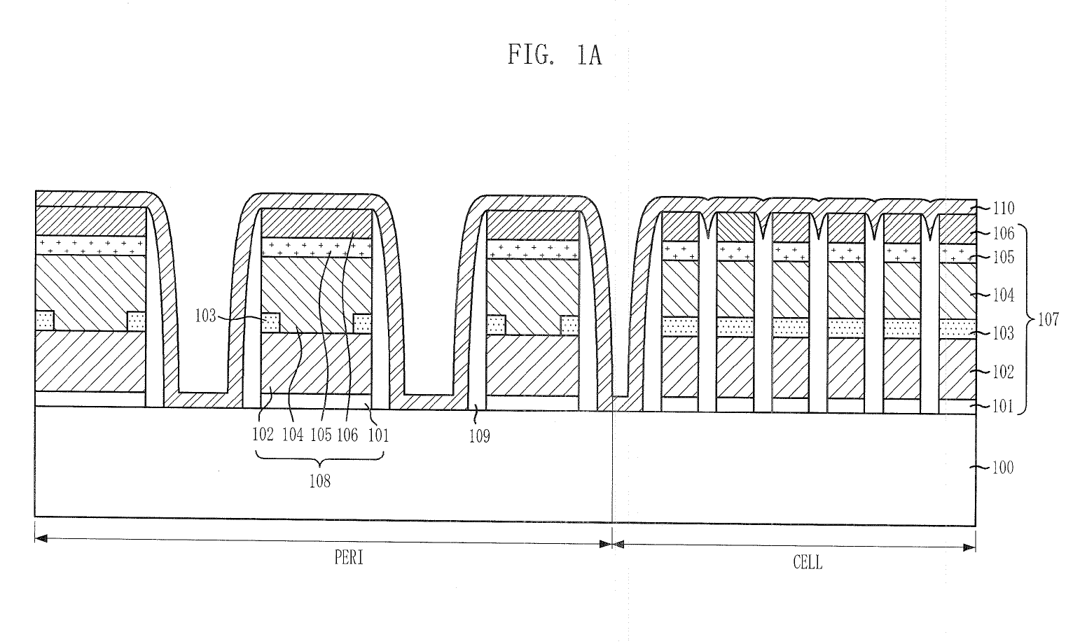

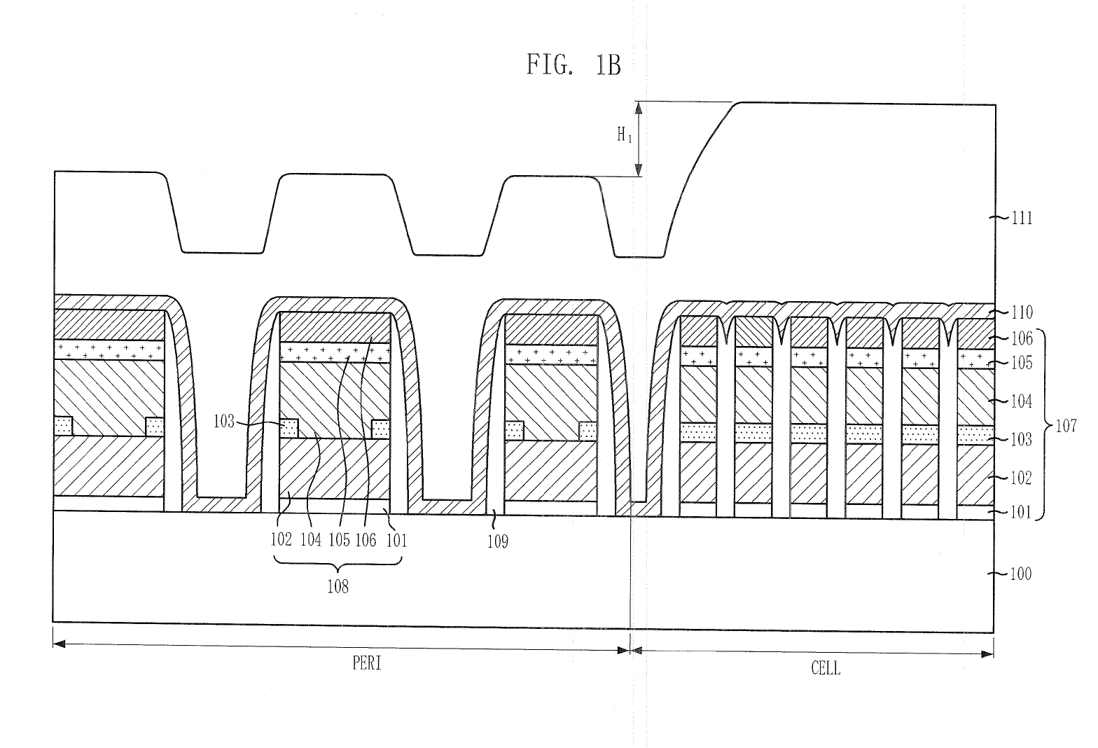

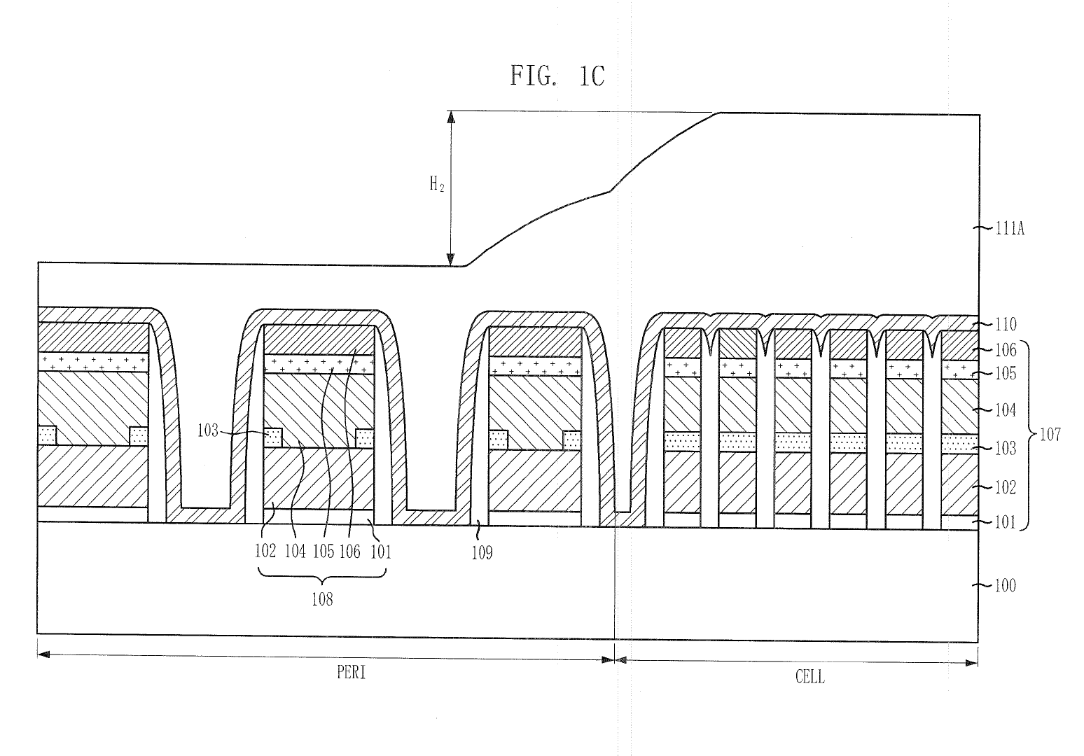

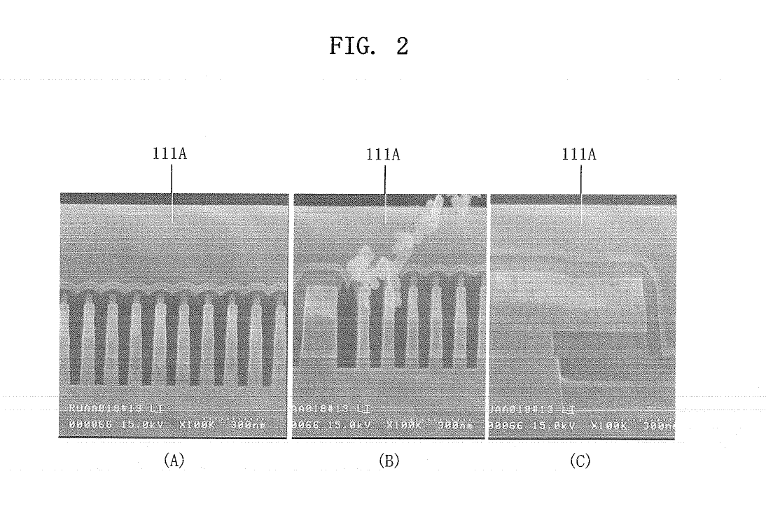

### DESCRIPTION OF SPECIFIC EMBODIMENTS

Embodiments of the present invention relate to a method for fabricating a semiconductor device.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals throughout the various embodiments of the present invention represent the same or like elements in different drawings.

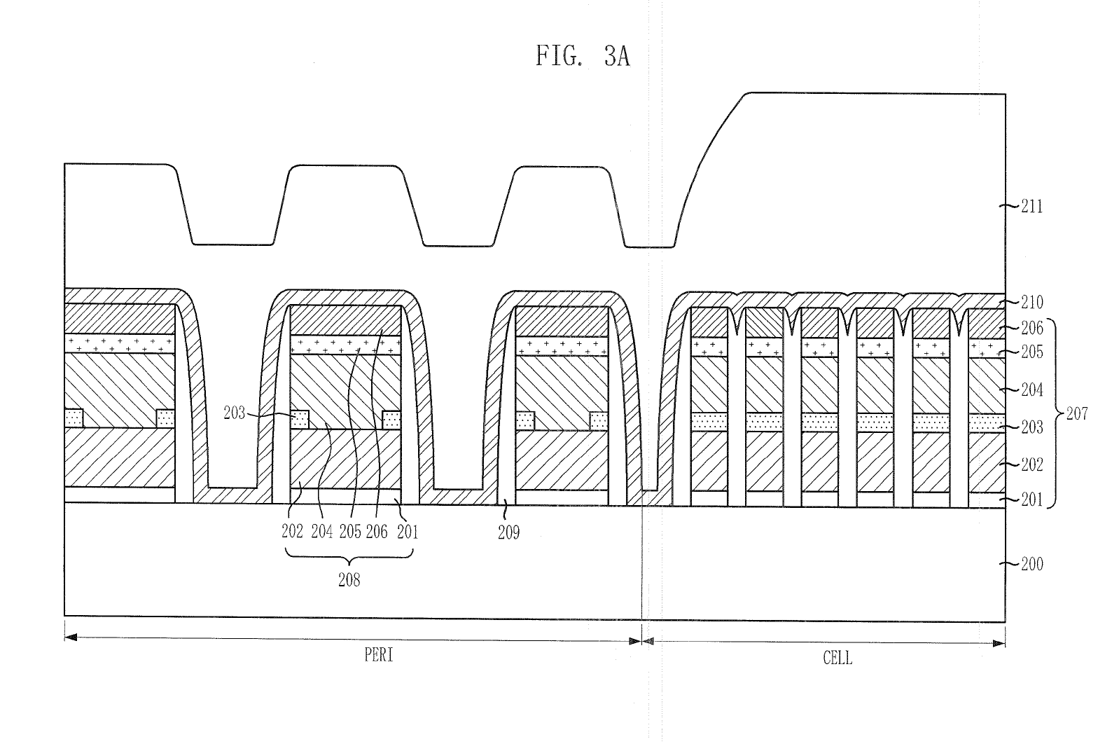

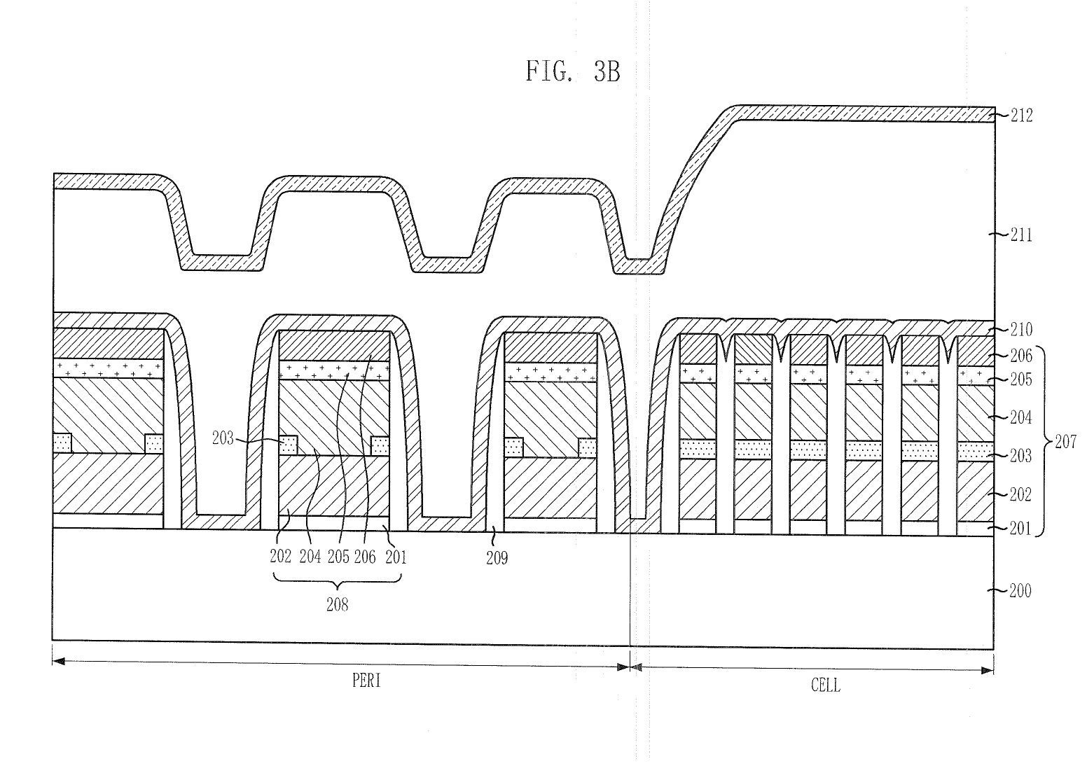

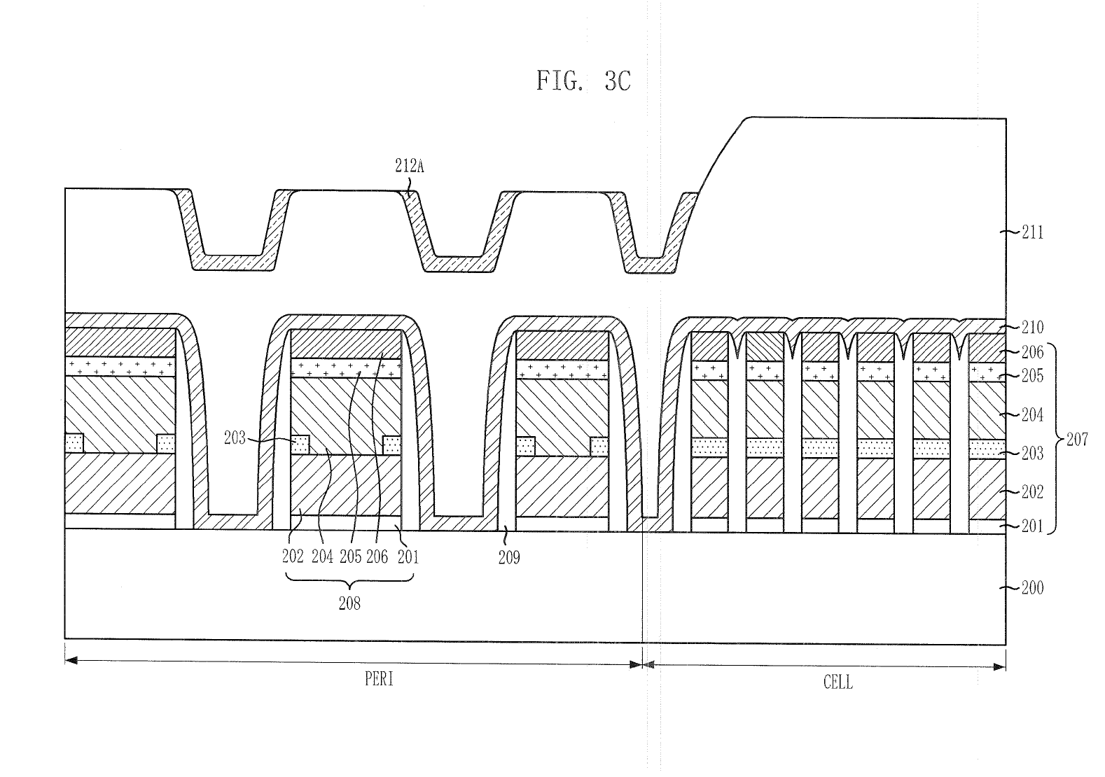

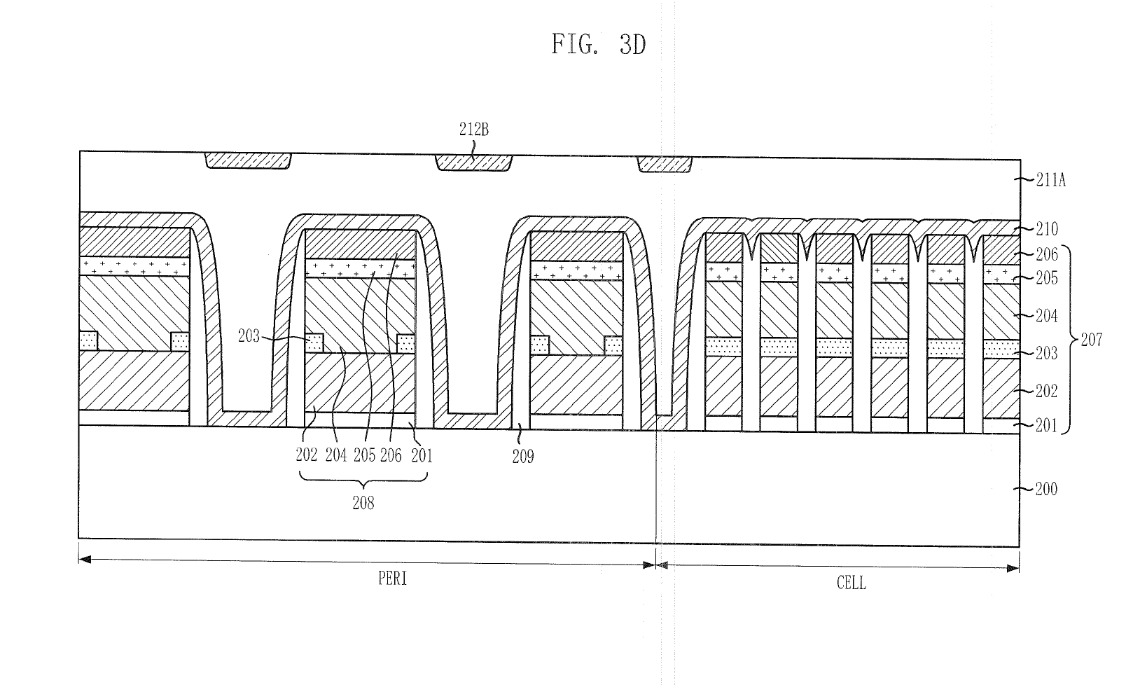

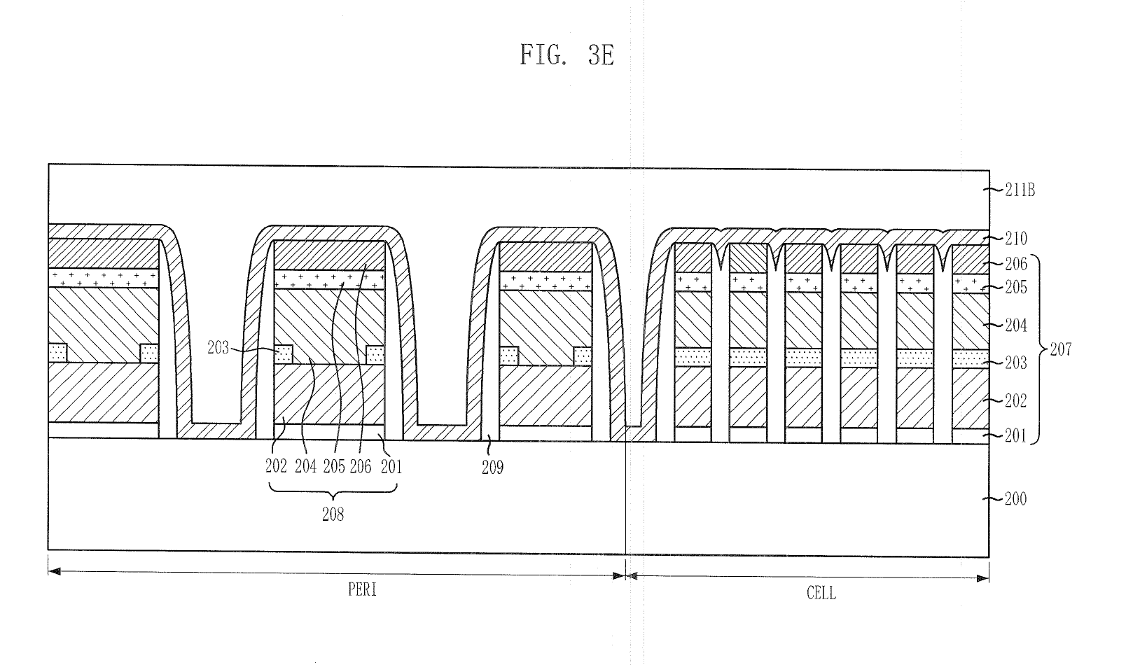

FIGS. 3A to 3E are cross-sectional views of a semiconductor device in accordance with an embodiment of the present invention. Although description will be focused on a method for fabricating a NAND flash memory device, it is for exemplary purposes only. Throughout the drawings, a symbol ‘CELL’ denotes a cell region, and a symbol ‘PERI’ denotes a peripheral region.

Referring to FIG. 3A, certain patterns are formed in the cell region CELL and the peripheral region PERI. For example, a first gate electrode 207 is formed in the cell region CELL and a second gate electrode 208 is formed in the peripheral region PERI. In one embodiment, the first gate electrode 207 has a smaller linewidth than the second gate electrode 208. Further, a space between the first gate electrodes 207 is relatively smaller than a space between the second gate electrodes 208.

The patterns formed in each of the cell region CELL and the peripheral region PERI are not limited to the first and second gate electrodes 207 and 208 as shown in FIGS. 3A to 3D. That is, each of the cell region CELL and the peripheral region PERI may include patterns with different pattern densities including a conductive layer, an insulation layer or a combination layer. The conductive layer and the insulation layer may be provided singly or in combination. In one embodiment, the conductive layer and the insulation layer may be provided in plurality, layered in alternation. However, as will be well appreciated, the conductive layers and insulation layers may be layered in any order. Additionally, the patterns may have equal or different linewidths and spaces therebetween, and may be provided on the same plane. For instance, the conductive layer may include a metal interconnection or a metal pad, and the insulation layer may be used as a dummy pattern having a predetermined pattern and formed on the same plane.

A spacer 209 is formed on both sidewalls of the first gate electrodes 207 and the second gate electrodes 208. The spacer 209 may include one layer selected from an oxide layer such as a silicon oxide layer, a nitride layer such as a silicon nitride layer, or multi-stacked layers thereof.

Although not shown, ion implantation layers (not shown), e.g., source and drain regions, are formed in a semiconductor substrate 200 exposed at both sides of the first gate electrodes 207 and the second gate electrodes 208.

An etch stop layer 210 is formed along top surfaces of the first gate electrodes 207 and second 208 as well as the spacer 209. It is preferable that the etch stop layer 210 may be formed of a material having a high etch selectivity ratio to a polish target layer, e.g., an insulation layer 211. For example, the etch stop layer includes a silicon nitride layer.

The polish target layer, e.g., the insulation layer 211, is deposited over the etch stop layer 210. The insulation layer 211 may have a single layer or a multi-layered structure including a plurality of layers with the same polish selectivity ratio (or the polish selectivity ratio close to approximately 1:1). For instance, the insulation layer 211 includes an oxide layer such as an undoped silica glass (USG), a borophosphosilicate glass (BPSG), a phosphosilicate glass (PSG), a borosilicate glass (BSG), a high density plasma (HDP) and a tetra ethyl ortho silicate (TEOS) layers. In addition, the insulation layer 211 may include a spin on dielectric (SOD) layer.

The polish target layer is not limited to the insulation layer 211, and thus it may be a conductive layer.

Referring to FIG. 3B, a planarization guide layer 212 is formed along the top surface of the insulation layer 211. The planarization guide layer 212 may include a material having a high polish selectivity ratio to the insulation layer 211. For instance, the planarization guide layer 212 may include a nitride layer, a polysilicon layer or a metal layer if the insulation layer 211 includes an oxide layer. Here, the metal layer includes a transition metal or a rare earth metal. In addition, the planarization guide layer 212 may be appropriately selected in consideration of a polish selectivity ratio with respect to the insulation layer 211 during the subsequent CMP process. It is preferable that the planarization guide layer 212 may be formed to a thickness ranging from approximately 100 Å to approximately 500 Å.

Referring to FIG. 3C, the CMP process is performed to selectively remove the planarization guide layer 212 formed in the cell region CELL. At this time, the planarization guide layer 212 of a region except for a bended portion is also removed in the peripheral region PERI. The CMP process is performed to completely remove the planarization guide layer 212 formed in the cell region CELL under the condition of high polish selectivity ratio of the planarization guide layer 212 to the insulation layer 211. As a result, a polished planarization guide layer 212A is formed after the CMP process.

For example, when the insulation layer 211 includes the oxide layer and the planarization layer 212 includes the nitride layer or the polysilicon layer, a slurry condition used in the CMP process can be set to Tables 1 and 2 below. Herein, Table 1 corresponds to the case where the planarization guide layer 212 includes the nitride layer, and Table 2 corresponds to the case where the planarization guide layer 212 includes the polysilicon layer.

TABLE 1

| | | | Removal | Removal | Selectivity |
|---|---|---|---|---|---|
| | | | Rate of | Rate of | Ratio |
| | Particle | | Nitride | Oxide | (Nitride |
| | Size | Acidity | Layer | Layer | Layer:Oxide |
| Abrasive | (nm) | (pH) | (Å/min) | (Å/min) | Layer) |
| Silica | 30-50, | 10-11 | 1,000-2,000 | ~10 | 100:1~200:1 |
| (SiO₂) | 60-100 | | | | |

TABLE 2

| | | | Removal | Removal | Selectivity |
|---|---|---|---|---|---|
| | | | Rate of | Rate of | Ratio |
| | Particle | | Poly-Si | Oxide | (Poly-Si |
| | Size | Acidity | Layer (Å/ | Layer | Layer:Oxide |
| Abrasive | (nm) | (pH) | min) | (Å/min) | Layer) |
| Silica | 30-50, | 9.5-12 | 1,000-2,000 | ~10 | 100:1~200:1 |
| (SiO₂) | 60-100 | | | | |

In the case where the planarization guide layer 212 includes the nitride layer as illustrated in Table 1, the CMP process is performed under the conditions that colloidal or fumed silica is used as abrasives and primary particles having a size of approximately 30 nm to approximately 50 nm are mixed together with secondary particles having a size of approximately 60 nm to approximately 100 nm. In this case, the acidity (pH) is maintained to approximately 10 to approximately 11. In addition, a polish selectivity ratio of the nitride layer to the oxide layer is in the range of approximately 100:1 to approximately 200:1, a removal rate of the nitride layer is in the range of approximately 1,000 Å/min to approximately 2,000 Å/min, and a removal rate of an oxide layer is 10 Å/min or less, preferably in the range of approximately 1 Å/min to 10 Å/min.

In the case where the planarization guide layer 212 includes the polysilicon layer as illustrated in Table 2, the CMP process is performed under the conditions that colloidal or fumed silica is used as abrasives and primary particles having a size of approximately 30 nm to approximately 50 nm are mixed together with secondary particles having a size of approximately 60 nm to approximately 100 nm. In this case, the acidity (pH) is maintained to approximately 9.5 to approximately 12. To selectively remove the planarization guide layer 212, an etch process, e.g., dry etch or wet etch, may be performed instead of the CMP process. In this case, a photoresist pattern (not shown) is formed such that it exposes the cell region CELL but covers the peripheral region PERI, and the etch process is then performed using the photoresist pattern as an etch mask. However, because a mask process is additionally required for performing the etch process, it is preferable to perform the CMP process instead of the etch process in terms of process simplification.

Referring to FIG. 3D, the CMP process is performed to planarize the cell region CELL and the peripheral region PERI. In one embodiment, the CMP process is performed under the condition that a polishing rate of the insulation layer 211 is higher than that of the polished planarization guide layer 212A, while maintaining a polish selectivity ratio of the polished planarization guide layer 212A to the insulation layer 211 to be lower than the polish selectivity ratio of the CMP process illustrated in FIG. 3C, thus planarizing the cell region CELL and the peripheral region PERI. As a result, a residual planarization guide layer 212B and a residual insulation layer 211A are formed. For instance, a slurry condition used in the CMP process may be set to Tables 3 and 4 below. Herein, Table 3 corresponds to the case where the polished planarization guide layer 212A includes the nitride layer, and Table 4 corresponds to the case where the polished planarization guide layer 212A includes the polysilicon layer.

TABLE 3

| | | | Removal | Removal | Selectivity |
|---|---|---|---|---|---|
| | | | Rate of | Rate of | Ratio |
| | Particle | | Nitride | Oxide | (Nitride |
| | Size | Acidity | Layer | Layer | Layer:Oxide |
| Abrasive | (nm) | (pH) | (Å/min) | (Å/min) | Layer) |
| Ceria | 50-100, | 6-8 | ~10 | 20-100 | 1:2~1:10 |
| (CeO₂) | 200-400 | | | | |

TABLE 4

| | | | Removal | Removal | Selectivity |
|---|---|---|---|---|---|
| | | | Rate of | Rate of | Ratio |
| | Particle | | Poly-Si | Oxide | (Poly-Si |
| | Size | Acidity | Layer (Å/ | Layer | Layer:Oxide |
| Abrasive | (nm) | (pH) | min) | (Å/min) | Layer) |
| Ceria | 50-100 | 6-8 | ~10 | 20-100 | 1:2~1:10 |
| (CeO₂) | 200-400 | | | | |

In the case where the polished planarization guide layer 212A includes a nitride layer as illustrated in Table 3, if the CMP process is performed under the conditions that ceria is used as abrasives and primary particles having a size of approximately 50 nm to approximately 100 nm are mixed together with secondary particles having a size of approximately 200 nm to approximately 400 nm. In this case, the pH is maintained to approximately 6 to approximately 8. In addition, a polish selectivity ratio of a nitride layer to an oxide layer is in the range of approximately 1:2 to approximately 1:10, a removal rate of the nitride layer is approximately 10 Å/min or less, preferably in the range of approximately 5 Å/min to approximately 8 Å/min, and a removal rate of an oxide layer is in the range of approximately 2 Å/min to approximately 100 Å/min.

In the case where the polished planarization guide layer 212A includes a polysilicon layer as illustrated in Table 4, the CMP process is performed under the conditions that ceria is used as abrasives and primary particles having a size of approximately 50 nm to approximately 100 nm are mixed together with secondary particles having a size of approximately 200 nm to approximately 400 nm. In this case, the pH is maintained to approximately 6 to approximately 8. A polish selectivity ratio of the polysilicon layer to the oxide layer is set to a range of approximately 1:2 to approximately 1:10.

Preferably, the CMP process illustrated in FIG. 3D may be performed until the step between the cell region CELL and the peripheral region PERI is completely removed, thus obtaining a uniformly planarized surface.

Referring to FIG. 3E, the CMP process may be further performed to remove the residual planarization guide layer 212B in the peripheral region PERI. In one embodiment, the CMP process may be performed under the condition of a polish selectivity ratio of approximately 1:1 using silica-based slurry so as to prevent a step, e.g., dishing phenomenon, from occurring between the cell region CELL and the peripheral region PERI.

The planarizing method in accordance with an embodiment of the present invention is performed on the residual insulation layer 211A, resulting in a planarized insulation layer 211B.

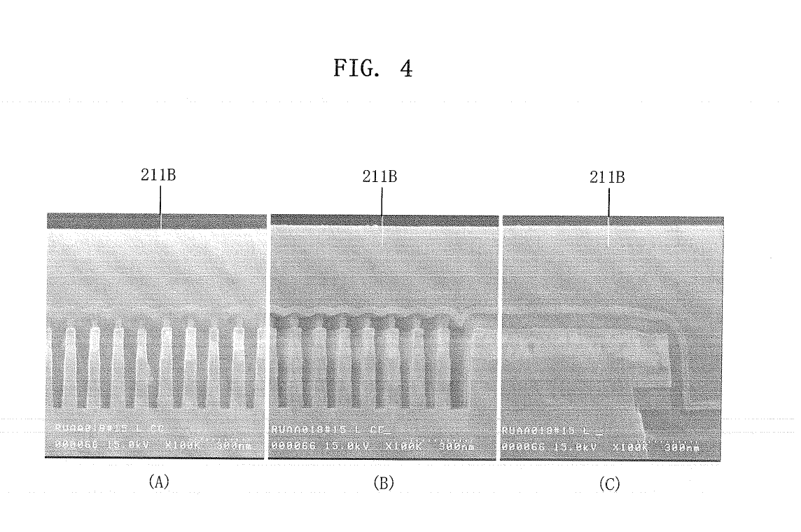

FIG. 4 is a micrographic view of a semiconductor device in accordance with the embodiment of the present invention. Referring to the micrographic views of FIG. 4 of a central portion (A) and an edge portion (B) in the cell region CELL and the peripheral region (C), it can be observed that there is no step therebetween. Referring back to FIGS. 3A to 3E, although not described in detail, it is noted that reference numeral 200 denotes a substrate, reference numeral 201 denotes a tunneling insulation layer (or a gate insulation layer), reference numeral 202 denotes a floating gate, reference numeral 203 denotes a dielectric layer, reference numeral 204 denotes a control gate (or a gate electrode), reference numeral 205 denotes a metal silicide layer, and reference numeral 206 denotes a hard mask layer.

In accordance with embodiments of the present invention, a planarization guide layer having a polish selectivity ratio with respect to a polish target layer is formed over the polish target layer covering respective regions with different pattern densities, and thereafter a CMP process is performed using this polish selectivity ratio of the planarization guide layer to the polish target layer, thus uniformly planarizing the polish target layer. Consequently, it is possible to effectively remove a step occurring between the regions with different pattern densities, and thus to improve device characteristics.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
providing a substrate including first and second regions of which each region has a plurality of patterns, the patterns in the first region having a pattern density different from the patterns in the second region;
forming a polish target layer over the substrate, wherein the polish target layer covers the plurality of patterns;
forming a planarization guide layer along a top surface of the polish target layer, the planarization guide layer having a polish selectivity ratio with respect to the polish target layer;
removing the planarization guide layer formed in the first region such that the planarization guide layer remains only in the second region having the patterns with low pattern density; and
polishing the remaining planarization guide layer and the polish target layer to remove a step between the first and the second regions.

2. The method of claim 1, wherein the plurality of patterns are formed over the same plane over the substrate.

3. The method of claim 1, wherein the polish target layer includes an insulation layer or a conductive layer.

4. The method of claim 1, wherein the insulation layer includes an oxide layer.

5. The method of claim 1, wherein the planarization guide layer includes a nitride layer or a polysilicon layer.

6. The method of claim 1, wherein the plurality of patterns include one selected from a group consisting of a conductive layer, an insulation layer and a combination thereof.

7. The method of claim 1, wherein a space between the patterns is greater in the second region than the first region.

8. The method of claim 1, wherein removing the planarization guide layer comprises selectively polishing the planarization guide layer formed in the second region using the polish selectivity ratio of the planarization guide layer to the polish target layer.

9. The method of claim 8, wherein removing the planarization guide layer is performed using silica abrasives.

10. The method of claim 1, wherein the polish selectivity ratio of the planarization guide layer to the polish target layer is in the range of approximately 100:1 to approximately 200:1.

11. The method of claim 11 wherein removing the planarization guide layer comprises:
forming a photoresist pattern that opens the first region and covers the second region; and
etching the planarization guide layer formed in the first region using the photoresist pattern as an etch mask.

12. The method of claim 1, wherein removing the step between the first and second regions is performed using ceria abrasives.

13. The method of claim 12, wherein removing the step between the first and the second regions is performed under the condition that the polish selectivity ratio of the remaining planarization guide layer to the polish target layer is in the range of approximately 1:2 to approximately 1:10.

14. The method of claim 1, wherein removing the step between the first and the second regions comprises:
performing a planarization process under the condition that a polish selectivity ratio of the remaining planarization guide layer to the polish target layer is in the range of approximately 1:2 to approximately 1:10and
performing a planarization process under the condition that a polish selectivity ratio of the remaining planarization guide layer to the polish target layer is approximately 1:1.

15. The method of claim 14, wherein performing the planarization process under the polish selectivity ratio in the range of approximately 1:2 to approximately 1:10 is carried out using ceria abrasives.

16. The method of claim 14, wherein performing the planarization process under the polish selectivity ratio of approximately 1:1 is carried using silica abrasives.

17. A method for fabricating a semiconductor device, the method comprising:
providing a substrate including a cell region and a peripheral region of which each region has a plurality of gate electrodes, the gate electrodes in the cell region having a density different from the gate electrodes in the peripheral region;
forming an insulation layer over the substrate, wherein the insulation layer covers the gate electrodes;
forming a planarization guide layer along a top surface of the insulation layer, the planarization guide layer having a polish selectivity ratio with respect to the insulation layer;
removing the planarization guide layer formed in the cell region such that the planarization guide layer remains only in the peripheral region having the gate electrodes with low density; and
polishing the remaining planarization guide layer and the insulation layer to remove a step between the cell region and the peripheral region.

18. The method of claim 17, wherein the insulation layer includes an oxide layer.

19. The method of claim 17, wherein a space between the gate electrodes is greater in the peripheral region than the cell region.

20. The method of claim 17, wherein the gate electrode formed in the cell region has a stacked structure where a tunneling insulation layer, a floating gate, a dielectric layer and a control gate are stacked.

21. The method of claim 17, wherein the polish selectivity ratio of the planarization guide layer to the insulation layer is in the range of approximately 100:1 to approximately 200:1.

22. The method of claim 17, wherein removing the step between the cell and peripheral regions is performed using ceria abrasives.

23. The method of claim 22, wherein removing the step between the cell and peripheral regions is performed under the condition that the polish selectivity ratio is in the range of approximately 1:2 to approximately 1:10.

24. The method of claim 17, wherein removing the step between the cell and peripheral regions comprises:
performing a planarization process under the condition that a polish selectivity ratio of the remaining planarization guide layer to the insulation layer is in the range of approximately 1:2 to approximately 1:10; and
performing a planarization process under the condition that a polish selectivity ratio of the remaining planarization guide layer to the insulation layer is approximately 1:1.

25. The method of claim 24, performing the planarization process under the polish selectivity ratio in the range of approximately 1:2 to approximately 1:10 and performing the planarization process under the polish selectivity ratio of approximately 1:1 are carried out using silica abrasives.
